(19) United States
(12) Patent Application Publication
(10) Pub. No.: US 2016/0202392 A1
(43) Pub. Date: Jul. 14, 2016

(54) DISPLAY SUBSTRATE AND FABRICATION METHOD THEREOF, AND DISPLAY APPARATUS AND FABRICATION METHOD THEREOF

(71) Applicant: BOE Technology Group Co., Ltd., Beijing (CN)

(72) Inventor: Yanbing Wu, Beijing (CN)

(21) Appl. No.: 14/808,032

(22) Filed: Jul. 24, 2015

(30) Foreign Application Priority Data
Jan. 14, 2015 (CN) 201510018732.8

(51) Int. Cl. G02B 1/11; H01L 27/15

(52) U.S. Cl. CPC G02B 1/11; H01L 27/156

(57) ABSTRACT

A display substrate and a fabrication method thereof, and a display apparatus and a fabrication method thereof are provided. The display substrate comprises a base substrate and a plurality of sub-pixel regions formed on a first surface of the base substrate. Each of the sub-pixel regions comprises a display region and a non-display region; and an anti-reflective layer is formed on a second surface of the base substrate, and the anti-reflective layer is provided to correspond to the non-display region.

This application claims priority to Chinese Patent Application No. 201510018732.8 filed on Jan. 14, 2015. The present application claims priority to and the benefit of the above-identified application and is incorporated herein in its entirety.

### TECHNICAL FIELD

Embodiments of the disclosure relate to a display substrate and a fabrication method thereof, and a display apparatus and a fabrication method thereof.

### BACKGROUND

A screen of a display apparatus generally contains glass, and reflectivity of the glass will lead to poor user experience during the user watches the image displayed by the display apparatus.

In general, the display apparatus comprises a color filter substrate and an array substrate provided opposite to each other, the color filter substrate includes a base substrate and a plurality of sub-pixel regions formed on a first surface of the base substrate, each sub-pixel region includes a display region and a non-display region, a colored resin pattern is provided in the display region, and a black matrix pattern is provided in the non-display region. The display region will emit light of certain intensity and certain color as required, while the non-display region is covered by the black matrix to shield circuits and wires provided on the array substrate or the color filter substrate. In practical applications, in the case that the screen of the display apparatus is in black, only reflected light will enter into the user's eyes, so that the user may see his own reflection clearly; and in the case that the screen of the display apparatus is displaying, the reflected light is barely perceptible to the user's eyes as the display light is stronger.

However, in the case that the non-display region of the display apparatus has a serious reflection phenomenon, high reflectivity in the non-display region will have an adverse influence on the display of the display region.

### SUMMARY

According to embodiments of the disclosure, a display substrate is provided. The display substrate comprises a base substrate and a plurality of sub-pixel regions formed on a first surface of the base substrate. Each of the sub-pixel regions comprises a display region and a non-display region; and an anti-reflective layer is formed on a second surface of the base substrate, and the anti-reflective layer is provided to correspond to the non-display region.

For example, the anti-reflective layer comprises a base layer and anti-reflective particles mixed in the base layer.

For example, the anti-reflective particles comprise particles of powdered carbon.

For example, the base layer is made from a resin.

For example, the anti-reflective particles have a diameter of 10 nm to 100 μm.

For example, the base layer has a thickness of 0.02 μm to 5 μm.

According to embodiments of the disclosure, a display apparatus is provided. The display apparatus comprises an opposed substrate and a display substrate provided to be opposed to each other. The display substrate comprises a base substrate and a plurality of sub-pixel regions formed on a first surface of the base substrate; each of the sub-pixel regions comprises a display region and a non-display region; and an anti-reflective layer is formed on a second surface of the base substrate, and the anti-reflective layer is provided to correspond to the non-display region.

For example, the anti-reflective layer comprises a base layer and anti-reflective particles mixed in the base layer.

For example, the anti-reflective particles comprise particles of powdered carbon.

For example, the base layer is made from a resin.

For example, the anti-reflective particles have a diameter of 10 nm to 100 μm.

For example, the base layer has a thickness of 0.02 μm to 5 μm.

According to embodiments of the disclosure, a fabrication method of a display substrate is provided. The method comprises: forming a plurality of sub-pixel regions on a first surface of a base substrate, each sub-pixel region comprising a display region and a non-display region; and forming an anti-reflective layer on a second surface of the base substrate, the anti-reflective layer being provided to correspond to the non-display region.

For example, the anti-reflective layer comprises: a base layer and anti-reflective particles mixed in the base layer. The forming the anti-reflective layer on the second surface of the base substrate comprises: mixing the anti-reflective particles into a base layer material; providing the base layer material in which the anti-reflective particles are mixed onto the second surface of the base substrate and patterning the base layer material to form the anti-reflective layer.

For example, the providing the base layer material in which the anti-reflective particles are mixed onto the second surface of the base substrate and patterning the base layer material to form the anti-reflective layer comprises: providing the base layer material in which the anti-reflective particles are mixed onto the second surface of the base substrate; irradiating the base layer material from the first surface of the base substrate, so that a portion of the base layer material which is provided to correspond to the display region is exposed to form an exposed portion and a portion of the base layer material which is provided to correspond to the non-display region is not exposed to form an unexposed portion; and developing the exposed base layer material to remove the exposed portion and reserve the unexposed portion to form the anti-reflective layer.

According to embodiments of the disclosure, a fabrication method of a display apparatus is provided. The method comprises: preparing a display substrate, the display substrate comprising a base substrate and a plurality of sub-pixel regions formed on a first surface of the base substrate, each of the sub-pixel regions comprising a display region and a non-display region; preparing an opposed substrate; providing the display substrate and the opposed substrate to be opposed to each other; and forming an anti-reflective layer on a second surface of the base substrate, the anti-reflective layer being provided to correspond to the non-display region.

For example, the anti-reflective layer comprises a base layer and anti-reflective particles mixed in the base layer. The forming the anti-reflective layer on the second surface of the base substrate comprises: mixing the anti-reflective particles into a base layer material; providing the base layer material in which the anti-reflective particles are mixed onto the second surface of the base substrate and patterning the base layer material to form the anti-reflective layer.

For example, providing the base layer material in which the anti-reflective particles are mixed onto the second surface of the base substrate and patterning the base layer material to form the anti-reflective layer comprises: providing the base layer material in which the anti-reflective particles are mixed onto the second surface of the base substrate; irradiating the base layer material from the opposed substrate, so that a portion the base layer material which is provided to correspond to the display region is exposed to form an exposed portion and a portion of the base layer material which is provided to correspond to the non-display region is not exposed to form an unexposed portion; and developing the exposed base layer material to remove the exposed portion and reserve the unexposed portion to form the anti-reflective layer.

For example, the anti-reflective layer is formed on the second surface of the base substrate after the display substrate and the opposed substrate are provided to be opposed to each other.

### BRIEF DESCRIPTION OF THE DRAWINGS

In order to clearly illustrate the technical solution of the embodiments of the disclosure, the drawings of the embodiments will be briefly described in the following; it is obvious that the described drawings are only related to some embodiments of the disclosure and thus are not limitative of the disclosure.

FIG. 1 is a structural schematic view illustrating a display substrate according to embodiments of the disclosure;

FIG. 2 is a flow chart illustrating a fabrication method of a display substrate according to embodiments of the disclosure;

FIG. 3a is a schematic view illustrating forming sub-pixel regions in the fabrication method of the display substrate according to the embodiments of the disclosure;

FIG. 3b is a schematic view illustrating providing a base layer material in the fabrication method of the display substrate according to the embodiments of the disclosure;

FIG. 3c is a schematic view illustrating exposing the base layer material in the fabrication method of the display substrate according to the embodiments of the disclosure;

FIG. 3d is a schematic view illustrating developing the exposed base layer material in the fabrication method of the display substrate according to the embodiments of the disclosure;

FIG. 4 is a flow chart illustrating a fabrication method of a display apparatus according to embodiments of the disclosure;

FIG. 5a is a schematic view illustrating providing a display substrate and an opposed substrate to be opposed to each other in the fabrication method of the display apparatus according to the embodiments of the disclosure;

FIG. 5b is a schematic view illustrating providing a base layer material in the fabrication method of the display apparatus according to the embodiments of the disclosure;

FIG. 5c is a schematic view illustrating exposing the base layer material in the fabrication method of the display apparatus according to the embodiments of the disclosure;

FIG. 5d is a schematic view illustrating developing the exposed base layer material in the fabrication method of the display substrate according to the embodiments of the disclosure; and

FIG. 5e is a schematic view illustrating post-baking the anti-reflective layer in the fabrication method of the display apparatus according to the embodiments of the disclosure.

### DESCRIPTION OF THE EMBODIMENTS

In order to make objects, technical details and advantages of the embodiments of the disclosure apparent, the technical solutions of the embodiment will be described in a clearly and fully understandable way in connection with the drawings related to the embodiments of the disclosure. It is obvious that the described embodiments are just a part but not all of the embodiments of the disclosure. Based on the described embodiments herein, those skilled in the art can obtain other embodiment(s), without any inventive work, which should be within the scope of the disclosure.

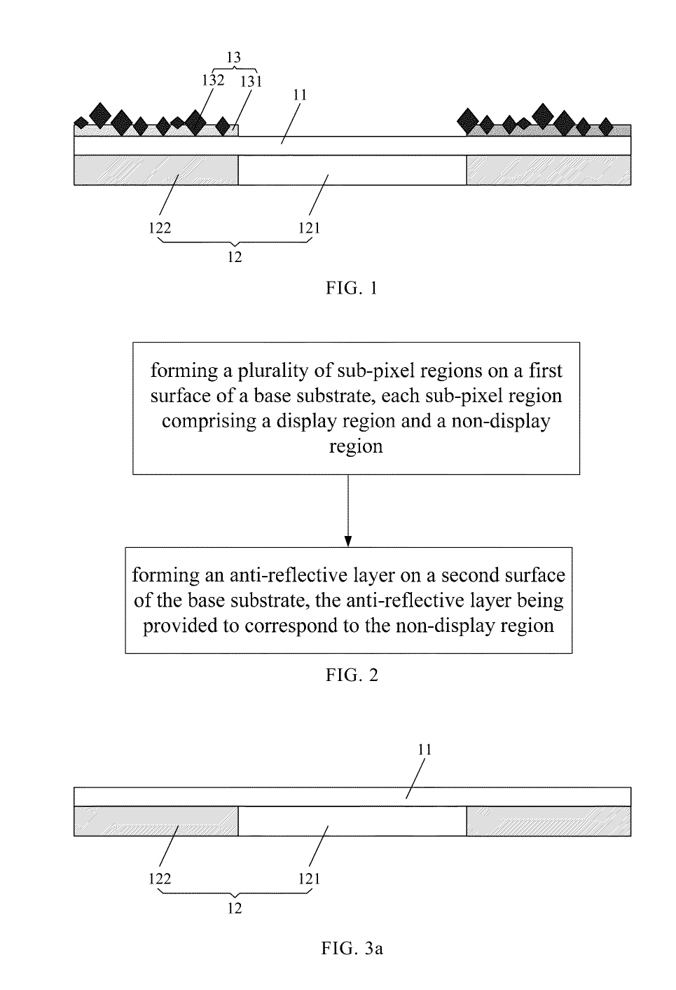

FIG. 1 is a structural schematic view illustrating a display substrate according to embodiments of the disclosure. As shown in FIG. 1, the display substrate includes a base substrate 11 and a plurality of sub-pixel regions 12 formed on a first surface of the base substrate 11, each sub-pixel region 12 includes a display region 121 and a non-display region 122, an anti-reflective layer 13 is formed on a second surface of the base substrate 11, and the anti-reflective layer 13 is provided to correspond to the non-display region 122. For example, the second surface of the base substrate 11 faces a user so that the user watches images displayed on the display substrate; and the first surface of the base substrate 11 is opposite to the second surface of the base substrate 11. For example, the plurality of sub-pixel regions 12 are provided in a matrix.

It should be noted that the anti-reflective layer 13 being provided to correspond to the non-display region 122 means that the anti-reflective layer 13 is provided within a region where the non-display region 122 is provided and has an area smaller than or equal to that of the non-display region 122.

For example, structures for display, such as a colored resin pattern, a driving electrode and the like, is provided in the display region 121. For example, a structure for separating the display regions 121 and/or a wiring structure, such as a black matrix pattern, a thin film transistor, a gate line, a data line and the like, is provided in the non-display region 122. The display region 121 is a transmissive region, while the non-display region 122 is a non-transmissive region.

For example, the display substrate is a color filter substrate, the colored resin pattern is provided in the display region 121, and the black matrix pattern is provided in the non-display region 122.

For example, the anti-reflective layer 13 includes: a base layer 131 and anti-reflective particles 132 mixed in the base layer 131. For example, the anti-reflective particles 132 are light-absorptive particles. Further, for example, the anti-reflective particles 132 include particles of powdered carbon. For example, the base layer 131 is made from a resin.

For example, the anti-reflective particles 132 each have a diameter of 10 nm to 100 μm. For example, the anti-reflective particles 132 have different diameters. For example, the base layer 131 has a thickness of 0.02 μm to 5 μm. Further, for example, the base layer 131 has a thickness of 1 μm.

The anti-reflective layer 13 is configured for absorbing or diffusing light incident on the non-display region, so as to reduce the reflected light in the non-display region. Specifically, the anti-reflective particles 132 are mixed in the base layer 131, and the anti-reflective particles 132 on a surface of the base layer 131 absorb or diffuse light incident on the non-display region. In the case that the anti-reflective particles 132 on the surface of the base layer 131 are of different diameters, a better light absorbing and diffusing effect can be achieved.

In the display substrate according to the embodiments of the disclosure, the anti-reflective layer is formed on the second surface of the base substrate of the display substrate, the anti-reflective layer is provided to correspond to the non-display region, and the anti-reflective layer absorbs or diffuses light incident on the non-display region so that the reflected light of the non-display region is reduced; therefore, adverse effect on the display region caused by the reflection phenomenon of the non-display region is reduced greatly.

Embodiments of the disclosure further provide a display apparatus. The display apparatus includes an opposed substrate and a display substrate provided to be opposed to each other. For example, the display substrate faces the user, and the display substrate is the display substrate as described above, details of which will not be repeated herein.

For example, the display substrate is a color filter substrate, and the opposed substrate is an array substrate.

For example, the display substrate may be an Organic Light-Emitting Diode (OLED) display substrate, an array substrate or a Color Filter On Array (COA) substrate.

The display apparatus according to the embodiments of the disclosure includes the display substrate which faces the user, the anti-reflective layer is formed on the second surface (the second surface faces the user) of the base substrate of the display substrate, the anti-reflective layer is provided to correspond to the non-display region, and the anti-reflective layer absorbs or diffuses light incident on the non-display region so that the reflected light of the non-display region is reduced; therefore, adverse effect on the display region caused by the reflecting phenomenon of the non-display region is reduced greatly.

Embodiments of the disclosure further provide a fabrication method of a display substrate. FIG. 2 is a flow chart of the fabrication method of the display substrate according to the embodiments of the disclosure. As shown in FIG. 2, the method comprises:

Step 101: forming a plurality of sub-pixel regions on a first surface of a base substrate, each sub-pixel region including a display region and a non-display region.

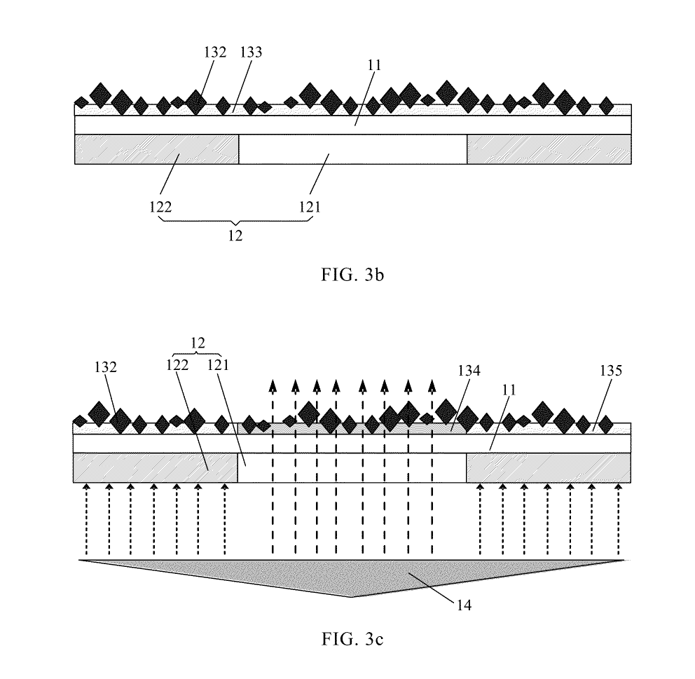

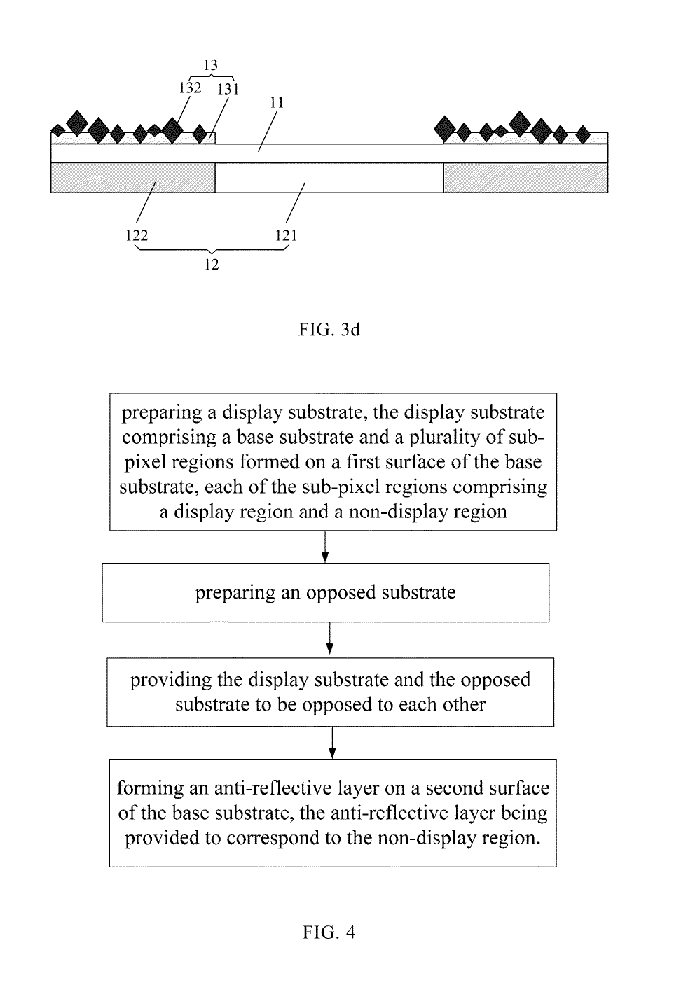

As shown in FIG. 3a, a plurality of sub-pixel regions 12 are formed on the first surface of the base substrate 11, and each sub-pixel region 12 includes a display region 121 and a non-display region 122. For example, the display substrate is a color filter substrate. Further, for example, a colored resin pattern is provided in the display region 121, and a black matrix pattern is provided in the non-display region 122.

Step 102: forming an anti-reflective layer on a second surface of the base substrate, the anti-reflective layer being provided to correspond to the non-display region.

For example, the second surface of the base substrate faces the user.

For example, the anti-reflective layer includes: a base layer and anti-reflective particles mixed in the base layer. In such case, the step 102 for example includes:

Step 1021: mixing the anti-reflective particles into a base layer material.

Step 1022: providing the base layer material in which the anti-reflective particles are mixed onto the second surface of the base substrate and patterning the base layer material to form the anti-reflective layer.

Further, for example, the step 1022 includes:

Step 1022a: providing the base layer material onto the second surface of the base substrate, the base layer material being mixed with the anti-reflective particles.

As shown in FIG. 3b, the base layer material 133 is coated on the second surface of the base substrate 11, the base layer material 133 is mixed with the anti-reflective particles 132.

Step 1022b: pre-baking the base layer material.

In such step, the base layer material is cured preliminarily by the pre-backing process.

Step 1022c: irradiating the base layer material from the first surface of the base substrate, so that a portion of the base layer material which is provided to correspond to the display region is exposed to form an exposed portion, and a portion of the base layer material which is provided to correspond to the non-display region is not exposed to form an unexposed portion.

As shown in FIG. 3c, a light source 14 is employed to irradiate the base layer material 133 from the first surface of the base substrate 11, so that the portion of the base layer material 133 which is provided to correspond to the display region 121 is exposed to form the exposed portion 134 and the portion of the base layer material 133 which is provided to correspond to the non-display region 122 is not exposed to form the unexposed portion 135.

Because the display region 121 is a light transmissive region, light emitted from the light source 14 will go through the display region 121 and expose the portion of the base layer material 133 which is provided to correspond to the display region 121. Because the non-display region 122 is a non-transmissive region, light emitted from the light source 14 is blocked by the non-display region 122 and will not go through the non-display region 122, and therefore the portion of the base layer material 133 which is provided to correspond to the non-display region 122 will not be exposed. For example, structures such as a black matrix pattern, a thin film transistor, a gate line, a data line and the like provided in the non-display region 122 will block light emitted from the light source 14. In the embodiments of the disclosure, the non-display region 122 blocks the light emitted from the light source 14 so that the base layer material is selectively exposed without employing a mask, that is, a self-alignment technique is employed; thereby the fabrication cost is reduced.

In practical applications, optionally, the light source may irradiate the base layer material from the second surface of the base substrate. In such case, a mask should be provided above the second surface of the base substrate; and in such case, a light-transmissive portion of the mask corresponds to the display region 121, and a non-transmissive portion of the mask corresponds to the non-display region.

Step 1022d: developing the exposed base layer material to remove the exposed portion and reserve the unexposed portion to form the anti-reflective layer.

As shown in FIG. 3d, the exposed base layer material is developed to remove the exposed portion 134 and reserve the unexposed portion to form the anti-reflective layer. During the exposed portion 134 is removed, both the exposed base layer material and the anti-reflective particles mixed therein are removed.

Step 1022e: post-baking the anti-reflective layer.

In such step, the anti-reflective layer is completely cured by the post-backing process, and the post-baked anti-reflective layer is as shown in FIG. 1.

The fabrication method of the display substrate according to the embodiments of the disclosure for example is applicable for preparing the display substrate as described above.

In the fabrication method of the display substrate according to the embodiments of the disclosure, the anti-reflective layer is formed on the second surface of the base substrate of the display substrate, the anti-reflective layer is provided to correspond to the non-display region, and the anti-reflective layer absorbs or diffuses light incident on the non-display region so that the reflected light of the non-display region is reduced; therefore, adverse effect on the display region caused by the reflecting phenomenon of the non-display region is reduced greatly.

According to the embodiments of the disclosure, a fabrication method of a display apparatus is further provided. FIG. 4 is a flow chart of the fabrication method of the display apparatus according to the embodiments of the disclosure. As shown in FIG. 4, the fabrication method of the display apparatus comprises:

Step 201: preparing a display substrate, the display substrate including a base substrate and a plurality of sub-pixel regions formed on a first surface of the base substrate, each of the sub-pixel regions including a display region and a non-display region.

The display substrate formed in such step for example is shown in FIG. 3a, and an anti-reflective layer has not been formed on a second surface of the base substrate of the display substrate.

Step 202: preparing an opposed substrate.

For example, the display substrate is a color filter substrate, and the opposed substrate is an array substrate.

Step 203: providing the display substrate and the opposed substrate to be opposed to each other.

The first surface of the base substrate of the display substrate faces the opposed substrate.

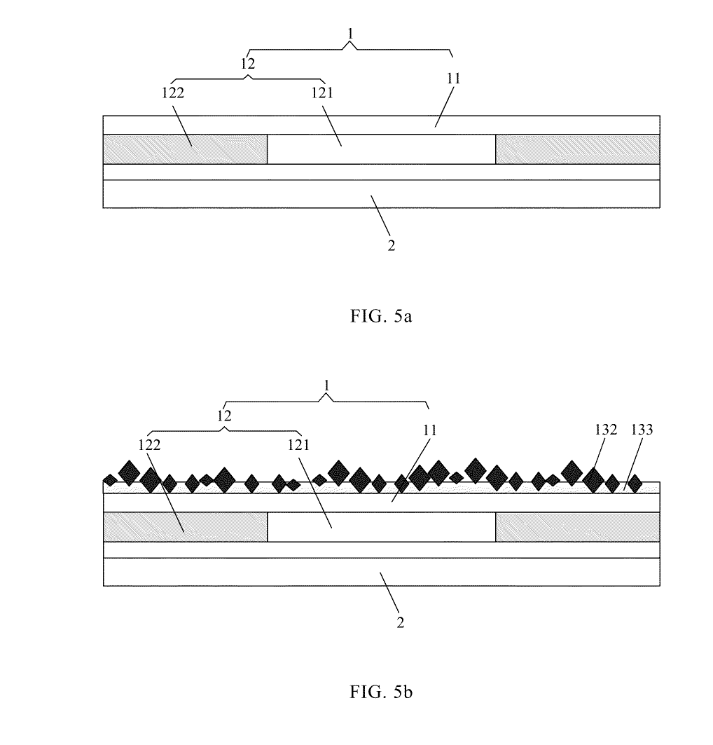

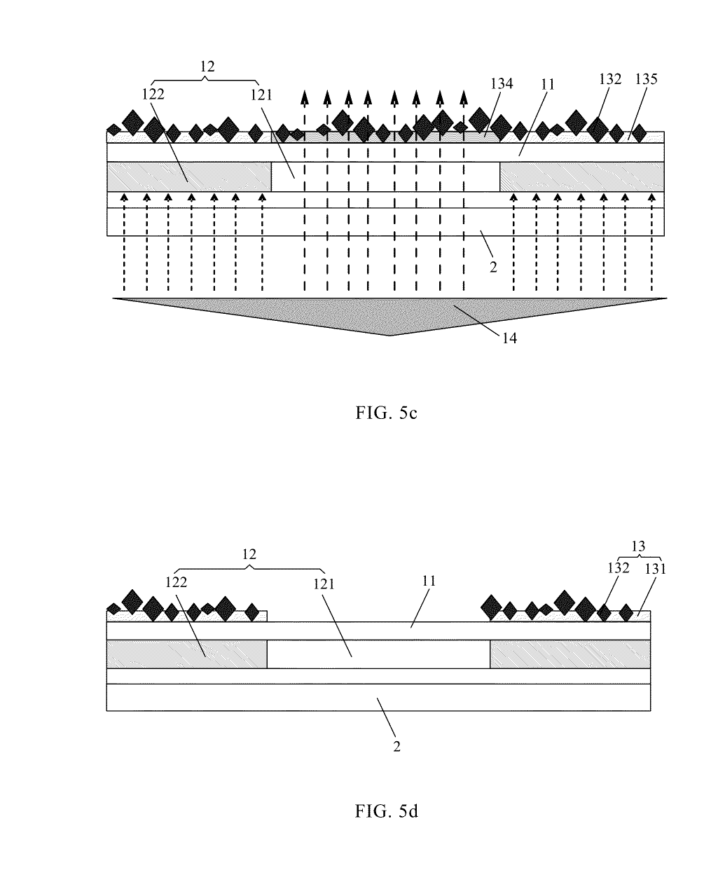

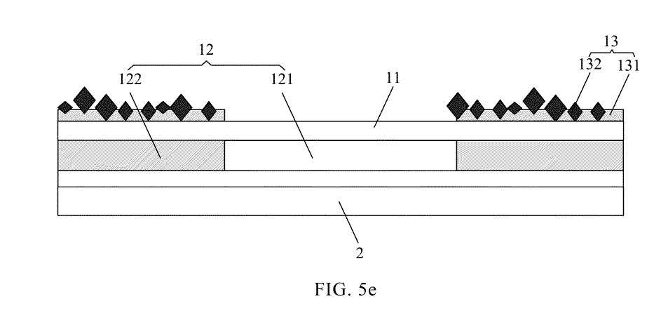

As shown in FIG. 5a, the display substrate 1 is bonded with the opposed substrate 2 to form the display apparatus. For example, the display apparatus is a liquid crystal display apparatus, and a liquid crystal layer (not shown) is further formed between the display substrate 1 and the opposed substrate 2.

Step 204: forming an anti-reflective layer on a second surface of the base substrate, the anti-reflective layer being provided to correspond to the non-display region.

For example, the anti-reflective layer includes a base layer and anti-reflective particles mixed in the base layer. In such case, the step 204 for example includes:

Step 2041: mixing the anti-reflective particles into a base layer material.

Step 2042: providing the base layer material onto the second surface of the base substrate and patterning the base layer material to form the anti-reflective layer.

Further, the step 2042 for example includes:

Step 2042a: providing the base layer material in which the anti-reflective particles are mixed onto the second surface of the base substrate.

As shown in FIG. 5b, the base layer material 133 is coated on the second surface of the base substrate 11, the base layer material 133 is mixed with the anti-reflective particles 132.

Step 2042b: pre-baking the base layer material.

In such step, the base layer material is cured preliminarily by the pre-backing process.

Step 2042c: irradiating the base layer material from the opposed substrate, so that a portion of the base layer material which is provided to correspond to the display region is exposed to form an exposed portion, and a portion of the base layer material which is provided to correspond to the non-display region is not exposed to form an unexposed portion.

As shown in FIG. 5c, a light source 14 is employed to irradiate the base layer material 133 from the opposed substrate 2, so that the portion of the base layer material 133 which is provided to correspond to the display region 121 is exposed to form the exposed portion 134, and the portion of the base layer material 133 which is provided to correspond to the non-display region 122 is not exposed to form the unexposed portion 135.

Because the display region 121 is a light-transmissive region, light emitted from the light source 14 will go through the display region 121 and expose the portion of the base layer material 133 which is provided to correspond to the display region 121. Because the non-display region 122 is a non-transmissive region, light emitted from the light source 14 is blocked by the non-display region 122 and will not go through the non-display region 122, and therefore the portion of the base layer material 133 which is provided to correspond to the non-display region 122 will not be exposed. In the embodiments of the disclosure, the non-display region 122 is employed to shield light emitted from the light source 14 so that the base layer material is selectively exposed without employing a mask, that is, a self-alignment technique is employed; thereby the fabrication cost is reduced.

In practical applications, optionally, the light source may irradiate the base layer material from the second surface of the base substrate. In such case, a mask plate should be provided above the second surface of the base substrate; and in such case, a light-transmissive portion of the mask corresponds to the display region 121, and a non-transmissive portion of the mask corresponds to the non-display region 122.

Step 2042d: developing the exposed base layer material to remove the exposed portion and reserve the unexposed portion to form the anti-reflective layer.

As shown in FIG. 5d, the exposed base layer material is developed to remove the exposed portion 134 and reserve the unexposed portion to form the anti-reflective layer 13. During the exposed portion 134 is removed, both the exposed base layer material and the anti-reflective particles mixed therein are removed.

Step 2042e: post-baking the anti-reflective layer.

As shown in FIG. 5e, the anti-reflective layer is completely cured by the post-backing process, and the post-baked anti-reflective layer is as shown in FIG. 5e.

The fabrication method of the display apparatus according to the embodiments of the disclosure for example is applicable for preparing the display apparatus as described above.

In a comparative example, the anti-reflective layer is firstly formed on the first surface of the base substrate of the display substrate, and then the display substrate on which the anti-reflective layer has been formed is bonded with the opposed substrate to form the display apparatus. However, in such case, as the surface of the anti-reflective layer is not flat, the following steps such as carrying the display substrate will be adversely affected, thus the bonding process will be adversely affected. In the embodiments of the disclosure, the anti-reflective layer is formed on the second surface of the base substrate of the display substrate after the display substrate is bonded with the opposed substrate. As the anti-reflective layer is formed after the bonding process, the adverse influence of the anti-reflective layer on the follow-up boding process in the case that the anti-reflective layer is formed firstly is avoided.

In the fabrication method of the display apparatus according to the embodiments of the disclosure, the anti-reflective layer is formed on the second surface of the base substrate of the display substrate, the anti-reflective layer is provided to correspond to the non-display region, and the anti-reflective layer absorbs or diffuses light incident on the non-display region so that the reflected light of the display region is reduced; therefore, effect on the display region caused by the reflecting phenomenon of the non-display region is reduced greatly.

The foregoing embodiments merely are exemplary embodiments of the disclosure, and not intended to define the scope of the disclosure, and the scope of the disclosure is determined by the appended claims.

The present application claims priority of Chinese Patent Application No. 201510018732.8 filed on Jan. 14, 2015, the disclosure of which is incorporated herein by reference in its entirety as part of the present application.

What is claimed is:

1. A display substrate, comprising: a base substrate and a plurality of sub-pixel regions formed on a first surface of the base substrate, wherein
each of the sub-pixel regions comprises a display region and a non-display region; and
an anti-reflective layer is formed on a second surface of the base substrate, and the anti-reflective layer is provided to correspond to the non-display region.

2. The display substrate according to claim 1, wherein the anti-reflective layer comprises a base layer and anti-reflective particles mixed in the base layer.

3. The display substrate according to claim 2, wherein the anti-reflective particles comprises particles of powdered carbon.

4. The display substrate according to claim 2, wherein the base layer is made from a resin.

5. The display substrate according to claim 2, wherein the anti-reflective particles have a diameter of 10 nm to 100 μm.

6. The display substrate according to claim 2, wherein the base layer has a thickness of 0.02 μm to 5 μm.

7. A display apparatus, comprising an opposed substrate and a display substrate provided to be opposed to each other, wherein
the display substrate comprises a base substrate and a plurality of sub-pixel regions formed on a first surface of the base substrate;
each of the sub-pixel regions comprises a display region and a non-display region; and
an anti-reflective layer is formed on a second surface of the base substrate, and the anti-reflective layer is provided to correspond to the non-display region.

8. The display apparatus according to claim 7, wherein the anti-reflective layer comprises a base layer and anti-reflective particles mixed in the base layer.

9. The display apparatus according to claim 8, wherein the anti-reflective particles comprise particles of powdered carbon.

10. The display apparatus according to claim 8, wherein the base layer is made from a resin.

11. The display apparatus according to claim 8, wherein the anti-reflective particles have a diameter of 10 nm to 100 μm.

12. The display apparatus according to claim 8, wherein the base layer has a thickness of 0.02 μm to 5 μm.

13. A fabrication method of a display substrate, comprising:
forming a plurality of sub-pixel regions on a first surface of a base substrate, each sub-pixel region comprising a display region and a non-display region; and
forming an anti-reflective layer on a second surface of the base substrate, the anti-reflective layer being provided to correspond to the non-display region.

14. The fabrication method of the display substrate according to claim 13, wherein
the anti-reflective layer comprises: a base layer and anti-reflective particles mixed in the base layer; and
the forming the anti-reflective layer on the second surface of the base substrate comprises:
mixing the anti-reflective particles into a base layer material;
providing the base layer material in which the anti-reflective particles are mixed onto the second surface of the base substrate and patterning the base layer material to form the anti-reflective layer.

15. The fabrication method of the display substrate according to claim 14, wherein the providing the base layer material in which the anti-reflective particles are mixed onto the second surface of the base substrate and patterning the base layer material to form the anti-reflective layer comprises:
providing the base layer material in which the anti-reflective particles are mixed onto the second surface of the base substrate;
irradiating the base layer material from the first surface of the base substrate, so that a portion of the base layer material which is provided to correspond to the display region is exposed to form an exposed portion and a portion of the base layer material which is provided to correspond to the non-display region is not exposed to form an unexposed portion; and
developing the exposed base layer material to remove the exposed portion and reserve the unexposed portion to form the anti-reflective layer.
